(19) United States
(12) Patent Application Publication
(10) Pub. No.: US 2024/0413805 A1
(43) Pub. Date: Dec. 12, 2024

(54) THERMISTOR-MOUNTING PIEZOELECTRIC RESONATOR DEVICE

(71) Applicant: DAISHINKU CORPORATION, Kakogawa-shi, Hyogo (JP)

(72) Inventor: Yoshinari MORIMOTO, Kakogawa-shi (JP)

(73) Assignee: DAISHINKU CORPORATION, Kakogawa-shi, Hyogo (JP)

(21) Appl. No.: 18/702,237

(22) PCT Filed: Oct. 24, 2022
(86) PCT No.: PCT/JP2022/039503

§ 371 Date: Apr. 17, 2024

(30) Foreign Application Priority Data
Nov. 1, 2021 (JP) 2021-178744
Nov. 1, 2021 (JP) 2021-178745

(51) Int. Cl. H03H 9/05; H01C 7/04; H03H 9/10; H03H 9/19

(52) U.S. Cl. CPC H03H 9/0547; H01C 7/04; H03H 9/1021; H03H 9/19

(57) ABSTRACT

A thermistor-mounting piezoelectric resonator device according to one or more embodiments may include includes: a sandwich type device; and a thin plate-like thermistor mounted on an outer surface of a first sealing member of the sandwich type device. The thin plate-like thermistor is located to be superimposed on at least a part of a vibrating part of the sandwich type device in plan view. A piezoelectric resonator plate of the sandwich type device includes: the vibrating part; an external frame part surrounding an outer periphery of the vibrating part; and a support part supporting the vibrating part by connecting the vibrating part to the external frame part. The thin plate-like thermistor is located to be superimposed on the external frame part on two sides, facing each other, of the sandwich type device.

### TECHNICAL FIELD

The present invention relates to a thermistor-mounting piezoelectric resonator device in which a thermistor is mounted on a piezoelectric resonator device having a sandwich structure.

### BACKGROUND ART

Recently, in various electronic devices, the operating frequencies have increased and the package sizes (especially, the heights) have decreased. According to such an increase in operating frequency and a reduction in package size, there is also a need for piezoelectric resonator devices (such as a crystal resonator and a crystal oscillator) to be adaptable to the increase in operating frequency and the reduction in package size.

In this kind of piezoelectric resonator devices, a housing is constituted of a package having a substantially rectangular parallelepiped shape. The package is constituted of: a first sealing member and a second sealing member both made of, for example, glass or crystal; and a piezoelectric resonator plate made of, for example, crystal. On respective main surfaces of the piezoelectric resonator plate, excitation electrodes are formed. The first sealing member and the second sealing member are laminated and bonded via the piezoelectric resonator plate. Thus, a vibrating part (excitation electrodes) of the piezoelectric resonator plate, which is disposed in the package (in the internal space), is hermetically sealed. Hereinafter, this laminated structure of the piezoelectric resonator device is referred to as a “sandwich structure”. Also, the piezoelectric resonator device having such a sandwich structure is referred to as a “sandwich type device”.

### PRIOR ART DOCUMENTS

### Patent Documents

[Patent Document 1] JP 5900582
[Patent Document 2] JP 5888347

### SUMMARY OF THE INVENTION

### Problems to be Solved by the Invention

As the piezoelectric resonator devices, thermistor-mounting piezoelectric resonator devices are widely used, on which a thermistor is mounted (for example, see Patent Documents 1 and 2). However, no product of a thermistor-mounting piezoelectric resonator device as a sandwich type device on which a thermistor is mounted has been known until now. Furthermore, the sandwich type device has problems that notably occur in this type of device. Thus, it is also necessary to solve these problems in the sandwich type device when the thermistor-mounting piezoelectric resonator devices are manufactured as sandwich type devices.

For example, the sandwich type device is a thin device with a reduced height, and thus, the excitation electrode in the inside thereof is likely to be affected by external noise. Accordingly, it is important to take measures against noise. In the case where the thermistor-mounting piezoelectric resonator device is made as a sandwich type device also, it is required to solve the above problem.

Also, the sandwich type device is a thin device with a reduced height, and thus, its strength is relatively low. In the case where the thermistor-mounting piezoelectric resonator device is made as a sandwich type device also, it is required to solve this problem.

The present invention was made in consideration of the above circumstances, an object of which is to use a thermistor to be mounted in order to solve the problems in the sandwich type device when a thermistor-mounting piezoelectric resonator device is made as the sandwich type device. Specifically, the first object of the present invention is to provide a thermistor-mounting piezoelectric resonator device as a sandwich type device that has excellent measures against noise. Also, the second object of the present invention is to provide a thermistor-mounting piezoelectric resonator device as a sandwich type device that has measures for improving the strength.

### Means for Solving the Problems

In order to solve the above problems, a thermistor-mounting piezoelectric resonator device according to a first aspect of the present invention includes: a piezoelectric resonator device having a sandwich structure; and a thin plate-like thermistor. In the piezoelectric resonator device, a piezoelectric resonator plate has a vibrating part. On a first main surface of the vibrating part, a first excitation electrode is formed, and on a second main surface thereof, a second excitation electrode is formed. A first sealing member is laminated so as to cover the first main surface side of the piezoelectric resonator plate, and a second sealing member is laminated so as to cover the second main surface side of the piezoelectric resonator plate. The piezoelectric resonator plate is thus bonded to the first sealing member and the second sealing member so as to form an internal space in which the vibrating part is hermetically sealed. The thin plate-like thermistor is mounted on an outer surface of the first sealing member of the piezoelectric resonator device. The thin plate-like thermistor is located so as to be superimposed on at least a part of the vibrating part in plan view.

With the above configuration, since the thin plate-like thermistor is located so as to be superimposed on the vibrating part of the piezoelectric resonator device, it can serve as a shield member with respect to the vibrating part.

Also, in the above-described thermistor-mounting piezoelectric resonator device, the thin plate-like thermistor may be located so as to be superimposed on whole of the first excitation electrode and the second excitation electrode in plan view.

With the above configuration, since the thin plate-like thermistor is superimposed on whole of the first excitation electrode and the second excitation electrode, the shield effect of the thin plate-like thermistor can be maximized.

Also, in the thin plate-like thermistor of the above-described thermistor-mounting piezoelectric resonator device, a common electrode may be formed on a first main surface of a thermistor flat plate as a single plate, and split electrodes may be formed on a second main surface thereof. The common electrode may be formed so as to cover almost whole of the first main surface of the thermistor flat plate.

With the above configuration, since the common electrode of the thin plate-like thermistor has a large area, the thin plate-like thermistor can be functioned in an advantageous manner as a shield member.

Also, in the thin plate-like thermistor of the above-described thermistor-mounting piezoelectric resonator device, a common electrode may be formed on a first main surface of a thermistor flat plate as a single plate, and split electrodes may be formed on a second main surface thereof. The split electrodes may occupy half or more of an area of the thermistor flat plate.

With the above configuration, since the split electrodes of the thin plate-like thermistor have a large area, the thin plate-like thermistor can be functioned in an advantageous manner as a shield member.

In order to solve the above problems, a thermistor-mounting piezoelectric resonator device according to a second aspect of the present invention includes: a piezoelectric resonator device having a sandwich structure; and a thin plate-like thermistor. In the piezoelectric resonator device, a piezoelectric resonator plate has a vibrating part. On a first main surface of the vibrating part, a first excitation electrode is formed, and on a second main surface thereof, a second excitation electrode is formed. A first sealing member is laminated so as to cover the first main surface side of the piezoelectric resonator plate, and a second sealing member is laminated so as to cover the second main surface side of the piezoelectric resonator plate. The piezoelectric resonator plate is thus bonded to the first sealing member and the second sealing member so as to form an internal space in which the vibrating part is hermetically sealed. The thin plate-like thermistor is mounted on an outer surface of the first sealing member of the piezoelectric resonator device. The piezoelectric resonator plate is provided with: the vibrating part; an external frame part surrounding an outer periphery of the vibrating part; and a support part supporting the vibrating part by connecting the vibrating part to the external frame part. The thin plate-like thermistor is located so as to be superimposed on the external frame part on two sides, facing each other, of the piezoelectric resonator device.

With the above configuration, since the thin plate-like thermistor is bonded to an outer peripheral part of the piezoelectric resonator device, that is, located so as to be superimposed on the external frame part, it is possible to ensure the strength of the thermistor-mounting piezoelectric resonator device.

Also, in the above-described thermistor-mounting piezoelectric resonator device, the thin plate-like thermistor and the piezoelectric resonator device may be electrically connected to each other via a conductive resin adhesive, and furthermore a gap between the thin plate-like thermistor and the piezoelectric resonator device may be filled with a non-conductive resin adhesive.

With the above configuration, since the thin plate-like thermistor is surface-bonded to the piezoelectric resonator device via the conductive resin adhesive and the non-conductive resin adhesive, it is possible to improve the thermal conductivity between the thin plate-like thermistor and the piezoelectric resonator device. In this way, it is possible to keep the temperature of the thin plate-like thermistor at a temperature close to that of the vibrating part of the piezoelectric resonator device. Also, by the surface bonding of the piezoelectric resonator device and the thin plate-like thermistor, it is possible to improve the strength of the thermistor-mounting piezoelectric resonator device.

Also, in the above-described thermistor-mounting piezoelectric resonator device, the conductive resin adhesive may have a thermal conductivity higher than that of the non-conductive resin adhesive.

With the above configuration, it is possible to further improve the thermal conductivity between the thin plate-like thermistor and the piezoelectric resonator device.

Also, in the above-described thermistor-mounting piezoelectric resonator device, the non-conductive resin adhesive may have a hardness higher than that of the conductive resin adhesive.

With the above configuration, it is possible to release stress between the thin plate-like thermistor and the piezoelectric resonator device while improving the strength of the package of the thermistor-mounting piezoelectric resonator device.

Also, in the above-described thermistor-mounting piezoelectric resonator device, the first sealing member and the second sealing member may be each made of a brittle material.

### Effects of the Invention

In a thermistor-mounting piezoelectric resonator device according to the first aspect of the preset invention, since a thin plate-like thermistor with electrodes having a large area is located so as to be superimposed on a vibrating part, it can serve as a shield member with respect to the vibrating part. Thus, it is possible to exert an advantageous effect that a thermistor-mounting piezoelectric resonator device is provided as a sandwich type device that has excellent measures against noise.

In a thermistor-mounting piezoelectric resonator device according to the second aspect of the preset invention, since a thin plate-like thermistor is bonded to an outer peripheral part of the sandwich type device, that is, located so as to be superimposed on the external frame part, it is possible to exert an advantageous effect that a thermistor-mounting piezoelectric resonator device is provided as a sandwich type device that has measures for improving the strength.

### BRIEF DESCRIPTION OF THE DRAWINGS

FIG. 1 is a plan view illustrating a thermistor-mounting piezoelectric resonator device as one embodiment of the present invention.

FIG. 2 is a cross-sectional view illustrating the thermistor-mounting piezoelectric resonator device of FIG. 1.

FIG. 3 is a plan view illustrating a first main surface of a piezoelectric resonator plate in a sandwich type device.

FIG. 4 is a plan view illustrating a second main surface of the piezoelectric resonator plate in the sandwich type device.

FIG. 5 is a plan view illustrating a first main surface of a first sealing member in the sandwich type device.

FIG. 6 is a plan view illustrating a second main surface of the first sealing member in the sandwich type device.

FIG. 7 is a plan view illustrating a first main surface of a second sealing member in the sandwich type device.

FIG. 8 is a plan view illustrating a second main surface of the second sealing member in the sandwich type device.

FIG. 9(a) is a top view of a thin plate-like thermistor. FIG. 9(b) is a bottom view of the thin plate-like thermistor.

FIG. 10 is an exploded perspective view illustrating respective components of a crystal resonator device with a thermistor according to Embodiment 2.

FIG. 11 is a plan view illustrating a first main surface of a piezoelectric resonator plate.

FIG. 12 is a plan view illustrating a second main surface (bottom surface) of a second sealing member.

FIG. 13 is a cross-sectional view taken from line A-A of FIG. 10 when the respective components of FIG. 10 are assembled.

FIG. 14 is a plan view illustrating a first main surface of a plate-like thermistor.

FIG. 15 is a plan view illustrating a second main surface of the plate-like thermistor.

FIG. 16 is a cross-sectional view illustrating another example of the plate-like thermistor.

### MODE FOR CARRYING OUT THE INVENTION

### Embodiment 1

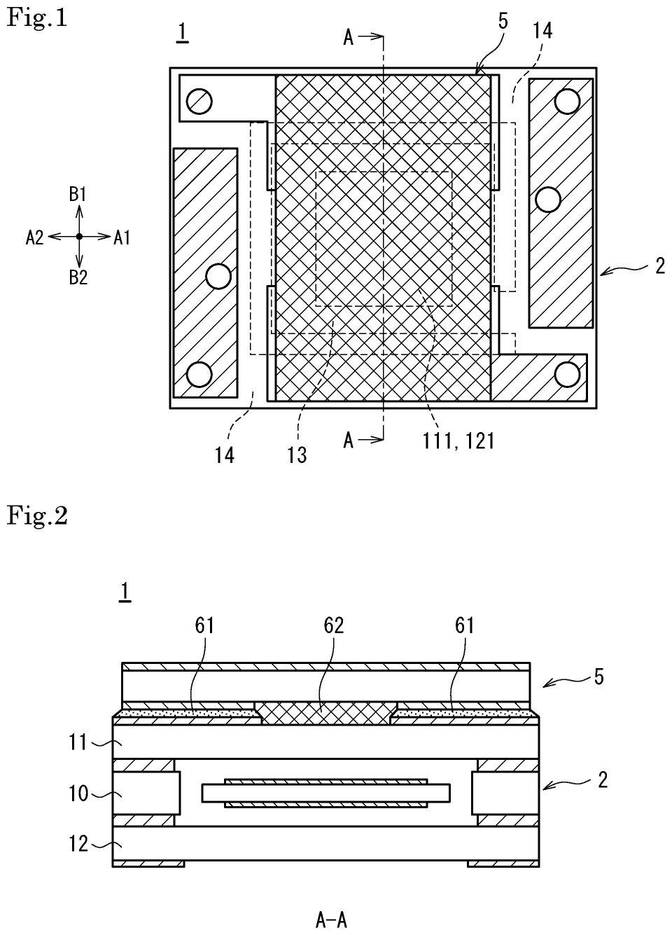

Hereinafter, an embodiment of the present invention will be described in detail with reference to the drawings. FIG. 1 is a plan view illustrating a thermistor-mounting piezoelectric resonator device (hereinafter referred to as “the device”) 1 according to this embodiment. FIG. 2 is a cross-sectional view (taken from line A-A of FIG. 1) that shows the device 1. As shown in FIGS. 1 and 2, the device 1 is a device with a thin plate-like thermistor 5 that is mounted on a sandwich type device (piezoelectric resonator device having a sandwich structure) 2.

Here, the configuration of the sandwich type device 2 is described. As shown in FIG. 2, the sandwich type device 2 includes: a piezoelectric resonator plate 10; a first sealing member 20; and a second sealing member 30. In the sandwich type device 2, the piezoelectric resonator plate 10 is bonded to the first sealing member 20, and also the piezoelectric resonator plate 10 is bonded to the second sealing member 30. Thus, a package having a sandwich structure is configured so as to have a substantially rectangular parallelepiped shape.

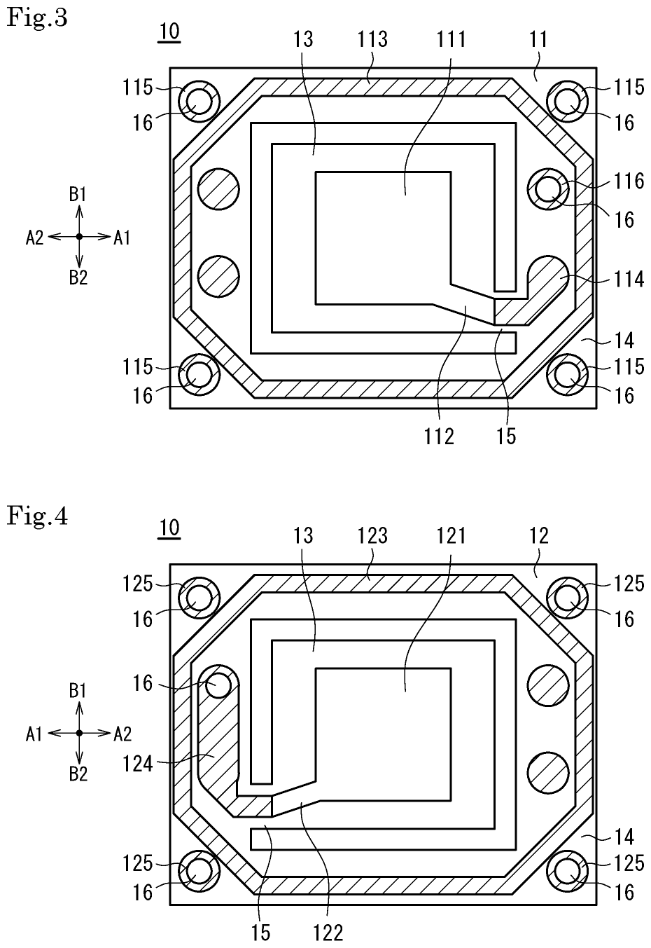

FIG. 3 is a plan view illustrating a first main surface 11 as one main surface (i.e. a surface to be bonded to the first sealing member 20) of the piezoelectric resonator plate 10 as a single body before bonding. FIG. 4 is a plan view illustrating a second main surface 12 as the other main surface (i.e. a surface to be bonded to the second sealing member 30) of the piezoelectric resonator plate 10 as a single body before bonding. The piezoelectric resonator plate 10 is a piezoelectric substrate made of a piezoelectric material such as crystal. Each main surface (i.e. the first main surface 11 and the second main surface 12) is formed as a smooth flat surface (mirror-finished). In this embodiment, an AT-cut crystal plate that causes thickness shear vibration is used as the piezoelectric resonator plate 10.

In FIGS. 3 to 8, the long-side direction of the piezoelectric resonator plate 10, the first sealing member 20 and the second sealing member 30 is indicated by an A1 direction and an A2 direction, while the short-side direction thereof is indicated by a B1 direction and a B2 direction. In the piezoelectric resonator plate 10, each main surface of the piezoelectric resonator plate 10 is an XZ′ plane. Also, the direction parallel to the short-side direction is an X axis direction, and the direction parallel to the long-side direction is a Z′ axis direction.

The piezoelectric resonator plate 10 includes: a vibrating part 13 formed so as to have a substantially rectangular shape; an external frame part 14 surrounding the outer periphery of the vibrating part 13; and a support part 15 that supports the vibrating part 13 by connecting the vibrating part 13 to the external frame part 14. Between the vibrating part 13 and the external frame part 14, a cutout part (i.e. an opening part penetrating the piezoelectric resonator plate 10 in the thickness direction) is formed except for a part on which the support part 15 is provided.

Thus, the piezoelectric resonator plate 10 has a configuration in which the vibrating part 13, the external frame part 14 and the support part 15 are integrally formed. On the first main surface 11 and the second main surface 12 of the piezoelectric resonator plate 10, a pair of excitation electrodes (i.e. a first excitation electrode 111 and a second excitation electrode 121) is respectively formed.

In this embodiment, the support part 15 is provided at only one position between the vibrating part 13 and the external frame part 14. The vibrating part 13 and the support part 15 each have a thickness less than a thickness of the external frame part 14. Due to the difference in thickness between the external frame part 14 and the support part 15, the natural frequency of piezoelectric vibration differs between the external frame part 14 and the support part 15. Thus, the external frame part 14 is not likely to resonate with the piezoelectric vibration of the support part 15. The support part 15 is not necessarily formed at one part. The support part 15 may be formed at each of two parts between the vibrating part 13 and the external frame part 14.

The first excitation electrode 111 is provided on the first main surface 11 side of the vibrating part 13 while the second excitation electrode 121 is provided on the second main surface 12 side of the vibrating part 13. The first excitation electrode 111 and the second excitation electrode 121 are respectively connected to lead-out wirings (i.e. a first lead-out wiring 112 and a second lead-out wiring 122) so that these excitation electrodes are connected to external electrode terminals. The first lead-out wiring 112 is drawn from the first excitation electrode 111 and connected to a connection bonding pattern 114 formed on the external frame part 14 via the support part 15. The second lead-out wiring 122 is drawn from the second excitation electrode 121 and connected to a connection bonding pattern 124 formed on the external frame part 14 via the support part 15.

On the first main surface 11 and the second main surface 12 of the piezoelectric resonator plate 10, bonding patterns are formed so as to bond the piezoelectric resonator plate 10 to the first sealing member 20 and also to the second sealing member 30. The bonding patterns include: sealing patterns to hermetically seal the internal space of the package; and conductive patterns to bring the wirings and electrodes into conduction. In FIGS. 3, 4, 6 and 7, bonding regions where the respective bonding patterns are formed are shown by hatched lines.

As the sealing patterns of the piezoelectric resonator plate 10, a resonator-plate-side first bonding pattern 113 is formed on the first main surface 11, and a resonator-plate-side second bonding pattern 123 is formed on the second main surface 12. The resonator-plate-side first bonding pattern 113 and the resonator-plate-side second bonding pattern 123 are each formed on the external frame part 14 so as to have an annular shape in plan view. The region inside the resonator-plate-side first bonding pattern 113 and the resonator-plate-side second bonding pattern 123 is a sealing region of the vibrating part 13 (i.e. a region to be the internal space of the package after bonding). The first excitation electrode 111 and the second excitation electrode 121 are not electrically connected to the resonator-plate-side first bonding pattern 113 and the resonator-plate-side second bonding pattern 123.

As the conductive patterns of the piezoelectric resonator plate 10, four connection bonding patterns 115 are formed on the first main surface 11, each at a position outside the sealing region (i.e. outside the resonator-plate-side first bonding pattern 113), and the connection bonding patterns 114 and 116 are formed inside the sealing region (i.e. inside the resonator-plate-side first bonding pattern 113). Also, four connection bonding patterns 125 are formed on the second main surface 12, each at a position outside the sealing region (i.e. outside the resonator-plate-side second bonding pattern 123), and the connection bonding pattern 124 is formed inside the sealing region (i.e. inside the resonator-plate-side first bonding pattern 113). The connection bonding patterns 115 and 125 are each provided on a corresponding region near the four corners (corner parts) of the external frame part 14.

In the piezoelectric resonator plate 10, a plurality of through holes 16 is formed between the first main surface 11 and the second main surface 12. Through electrodes are each formed on an inner wall surface of the respective through holes 16 so as to establish conduction between the first main surface 11 and the second main surface 12. More specifically, four through holes 16 (and their respective through electrodes) are formed so as to establish conduction between the connection bonding patterns 115 and the connection bonding patterns 125, and one through hole 16 (and its through electrode) is formed so as to establish conduction between the connection bonding pattern 116 and the connection bonding pattern 124.

In the piezoelectric resonator plate 10, it is possible to form, by the same process, the first excitation electrode 111, the second excitation electrode 121, the first lead-out wiring 112, the second lead-out wiring 122, the resonator-plate-side first bonding pattern 113, the resonator-plate-side second bonding pattern 123 and the connection bonding patterns 114-116, 124 and 125. More specifically, they can be each made of a base film (Ti film) deposited on each main surface of the piezoelectric resonator plate 10 by physical vapor deposition, and a bonding film (Au film) deposited on the base film by physical vapor deposition. Also, the configuration of the laminated film that forms the bonding pattern is not limited to the two layer structure of the Ti film and the Au film, but may be a three or more layer structure including another film (for example, a barrier film formed between the Ti film and the Au film).

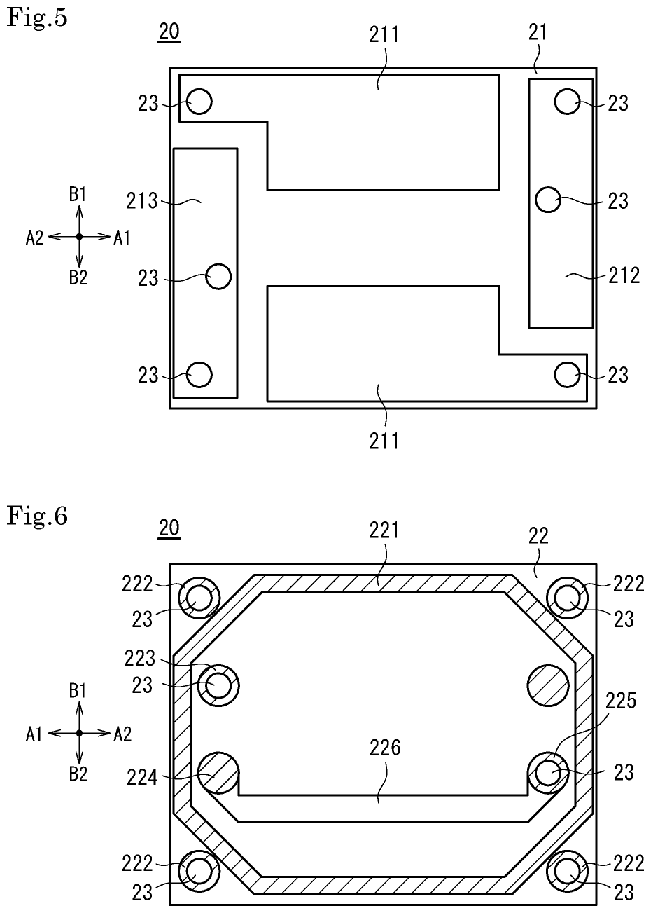

FIG. 5 is a plan view illustrating a first main surface 21 as one main surface (i.e. an outer surface) of the first sealing member 20 as a single body before bonding.

FIG. 6 is a plan view illustrating a second main surface 22 as the other main surface (i.e. a surface to be bonded to the piezoelectric resonator plate 10) of the first sealing member 20 as a single body before bonding. The first sealing member 20 is a substrate having a rectangular parallelepiped shape, which is made of a single glass wafer or a single crystal wafer. The second main surface 22 of the first sealing member 20 is formed as a smooth flat surface (mirror-finished).

As shown in FIG. 5, two electrode patterns 211 and wiring patterns 212 and 213 are formed on the first main surface 21 of the first sealing member 20. The electrode patterns 211 are mounting pads on which the thin plate-like thermistor 5 is mounted (see FIG. 1). The wiring pattern 212 is a wiring pattern that serves as a part of a wiring route to connect the first excitation electrode 111 to an external electrode terminal 321 (see FIG. 8). The wiring pattern 213 is a wiring pattern that serves as a part of a wiring route to connect the second excitation electrode 121 to an external electrode terminal 321.

On the second main surface 22 of the first sealing member 20, bonding patterns are formed so as to bond the first sealing member 20 to the piezoelectric resonator plate 10, as shown in FIG. 6. The bonding patterns include: a sealing pattern to hermetically seal the internal space of the package; and conductive patterns to bring the wirings and electrodes into conduction.

As the sealing pattern of the first sealing member 20, a sealing-member-side first bonding pattern 221 is formed. The sealing-member-side first bonding pattern 221 is formed so as to have an annular shape in plan view, and the region inside thereof is the sealing region. As the conductive patterns of the first sealing member 20, four connection bonding patterns 222 are formed each at a corresponding position outside the sealing region (i.e. outside the sealing-member-side first bonding pattern 221) near the four corners (corner parts).

Also, connection bonding patterns 223-225 are formed inside the sealing region (i.e. inside the sealing-member-side first bonding pattern 221). The connection bonding pattern 224 and the connection bonding pattern 225 are connected to each other via a wiring pattern 226.

In the first sealing member 20, a plurality of through holes 23 is formed between the first main surface 21 and the second main surface 22. Through electrodes are each formed on an inner wall surface of the respective through holes 23 so as to establish conduction between the first main surface 21 and the second main surface 22. More specifically, four through holes 23 (and their respective through electrodes) are formed so as to establish conduction between the electrode patterns 211/the wiring patterns 212 and 213, and the connection bonding patterns 222. One through hole 23 (and its through electrode) is formed so as to establish conduction between the wiring pattern 212 and the connection bonding pattern 223. Also, one through hole 23 (and its through electrode) is formed so as to establish conduction between the wiring pattern 213 and the connection bonding pattern 225.

In the first sealing member 20, it is possible to form, by the same process, the sealing-member-side first bonding pattern 221, the connection bonding patterns 222 to 225 and the wiring pattern 226. More specifically, they can be each made of a base film (Ti film) deposited on the second main surface 22 of the first sealing member 20 by physical vapor deposition, and a bonding film (Au film) deposited on the base film by physical vapor deposition.

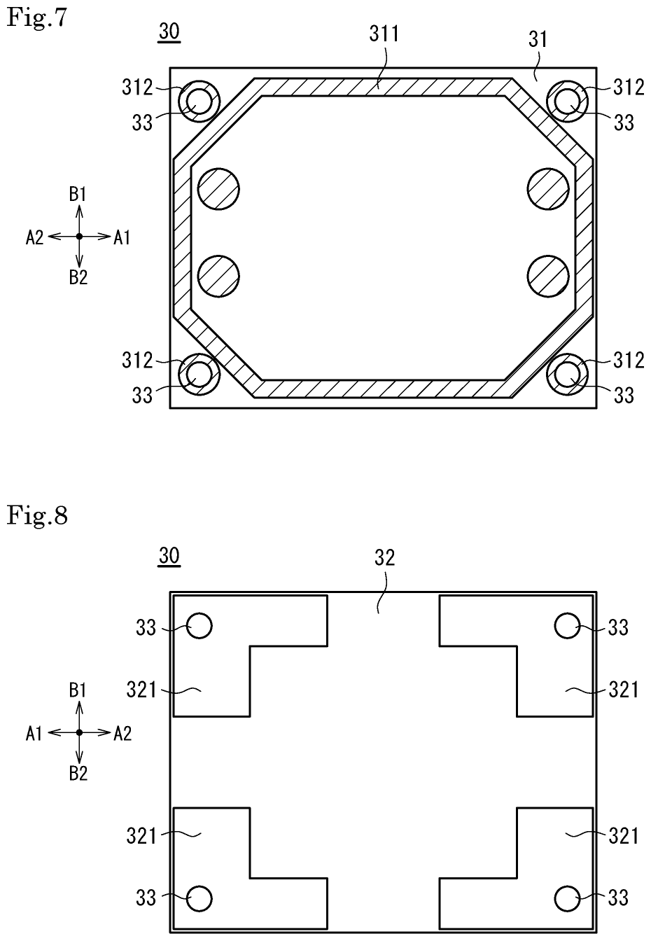

FIG. 7 is a plan view illustrating a first main surface 31 as one main surface (i.e. a surface to be bonded to the piezoelectric resonator plate 10) of the second sealing member 30 as a single body before bonding. FIG. 8 is a plan view illustrating a second main surface 32 as the other main surface (i.e. an outer surface) of the second sealing member 30 as a single body before bonding. The second sealing member 30 is a substrate having a rectangular parallelepiped shape, which is made of a single glass wafer or a single crystal wafer. The first main surface 31 of the first sealing member 20 is formed as a smooth flat surface (mirror-finished).

On the first main surface 31 of the second sealing member 30, bonding patterns are formed so as to bond the second sealing member 30 to the piezoelectric resonator plate 10, as shown in FIG. 7. The bonding patterns include: a sealing pattern to hermetically seal the internal space of the package; and conductive patterns to bring the wirings and electrodes into conduction.

As the sealing pattern of the second sealing member 30, a sealing-member-side second bonding pattern 311 is formed. The sealing-member-side second bonding pattern 311 is formed so as to have an annular shape in plan view, and the region inside thereof is the sealing region. As the conductive patterns of the second sealing member 30, four connection bonding patterns 312 are formed each at a corresponding position outside the sealing region (i.e. outside the sealing-member-side second bonding pattern 311) near the four corners (corner parts).

On the second main surface 32 of the second sealing member 30, four external electrode terminals 321 are formed as shown in FIG. 8, via which the device 1 is electrically connected to the outside. The external electrode terminals 321 are respectively located on four corners (corner parts) of the second sealing member 30.

In the second sealing member 30, a plurality of through holes 33 is formed between the first main surface 31 and the second main surface 32. Through electrodes are each formed on an inner wall surface of the respective through holes 33 so as to establish conduction between the first main surface 31 and the second main surface 32. More specifically, four through holes 33 (and their respective through electrodes) are formed so as to establish conduction between the connection bonding patterns 312 and the external electrode terminals 321.

In the second sealing member 30, it is possible to form, by the same process, the sealing-member-side second bonding pattern 311 and the connection bonding patterns 312. More specifically, they can be each made of a base film (Ti film) deposited on the first main surface 31 of the second sealing member 30 by physical vapor deposition, and a bonding film (Au film) deposited on the base film by physical vapor deposition.

In the sandwich type device 2, the piezoelectric resonator plate 10 and the first sealing member 20 are subjected to the diffusion bonding in a state in which the resonator-plate-side first bonding pattern 113 and the sealing-member-side first bonding pattern 221, both of which are the sealing patterns, are superimposed on each other. Also, the piezoelectric resonator plate 10 and the second sealing member 30 are subjected to the diffusion bonding in a state in which the resonator-plate-side second bonding pattern 123 and the sealing-member-side second bonding pattern 311, both of which are the sealing patterns, are superimposed on each other. Thus, the package having the sandwich structure is produced. That is, the resonator-plate-side first bonding pattern 113 and the sealing-member-side first bonding pattern 221 are bonded to each other so as to be a sealing pattern layer between the piezoelectric resonator plate 10 and the first sealing member 20, and the resonator-plate-side second bonding pattern 123 and the sealing-member-side second bonding pattern 311 are bonded to each other so as to be a sealing pattern layer between the piezoelectric resonator plate 10 and the second sealing member 30. In this way, the internal space of the package, i.e. the space to house the vibrating part 13 is hermetically sealed.

In the same time, the respective connection bonding patterns as the conductive patterns are also each bonded to the corresponding connection bonding pattern. The respective pairs of conductive patterns bonded to each other are conductive pattern layers between the piezoelectric resonator plate 10 and the first sealing member 20 or between the piezoelectric resonator plate 10 and the second sealing member 30. In the sandwich type device 2, such bonding allows electrical conduction between the first and second excitation electrode 111 and 121, and the external electrode terminals 321 (located at the bottom right part and at the top left part in FIG. 8). Also, the bonding allows electrical conduction between the thin plate-like thermistor 5 mounted on the sandwich type device 2 and the external electrode terminals 321 (located at the top right part and at the bottom left part in FIG. 8).

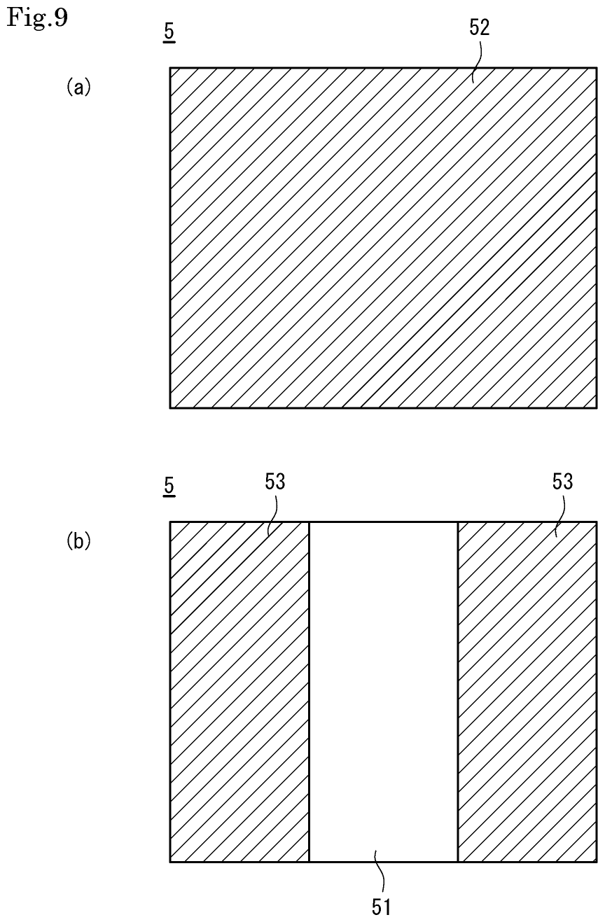

FIG. 9 (a) is a top view of the thin plate-like thermistor 5. FIG. 9 (b) is a bottom view of the thin plate-like thermistor 5. The thin plate-like thermistor 5 is an NTC thermistor thinned so as to be suitable for combination with the sandwich type device 2. In the thin plate-like thermistor 5, a common electrode 52 that serves as a relay electrode is formed on a first main surface of a thermistor flat plate 51 as a single plate, and split electrodes 53 that serve as working electrodes are formed on a second main surface thereof. In the device 1, the thickness of the sandwich type device 2 is about 120 μm, while the thickness of the thin plate-like thermistor 5 can be half or less of the thickness of the sandwich type device 2 (about 50 μm).

As the thermistor flat plate 51, a manganese semiconductor ceramic plate is, for example, used. More specifically, a Mn—Fe—Ni material is made into slurry with a binder. Then, the thermistor flat plate 51 in a wafer state is prepared as a green sheet using a thick film formation technology such as a screen printing technology or a doctor blade technology. This is subjected to firing technology so as to sinter and form the wafer thermistor flat plate 51. The above material is not limited to the Mn—Fe—Ni material. A Mn—Co material or an Fe—Ni material may also be used.

The common electrode 52 is formed so as to cover the whole (or almost the whole) surface of the thermistor flat plate 51. The split electrodes 53 are located on both end parts of the thermistor flat plate 51 in one direction (preferably, in the long-side direction), and occupy half or more of the area of the thermistor flat plate 51. As to each electrode, an electrode film (metal film) is formed on the thermistor flat plate 51 by sputtering, and then patterning is performed by a photolithography technology. As specific metal materials, a Ti film, a NiTi film and an Au film may be used so as to make a laminated structure. Also, other types of metal films may be used. In the case where the above laminated structure constituted of the Ti film, the NiTi film and the Au film is adopted, it is possible to perform stable conductive bonding with low occurrence of solder leaching when the thin plate-like thermistor 5 is finally bonded to the mounting board (in this case, the first sealing member 20) by solder.

In this way, since the thin plate-like thermistor 5 has metal electrodes each having a large area (i.e. the common electrode 52 and the split electrodes 53), it can function in an advantageous manner as a shield member to the sandwich type device 2. In order to cause the thin plate-like thermistor 5 to also function as the shield member, the thin plate-like thermistor 5 is located such that at least a part thereof is superimposed on the vibrating part 13 of the sandwich type device 2 in plan view of the device 1 (see FIG. 1). Furthermore, the thin plate-like thermistor 5 is preferably located so as to be superimposed on the whole of the first excitation electrode 111 and the second excitation electrode 121 in plan view because in such a case the shield effect of the thin plate-like thermistor 5 is maximized.

Also, the thin plate-like thermistor 5 is located such that both end parts thereof are superimposed on the external frame part 14, on at least two sides, facing each other, of the sandwich type device 2. The first sealing member 20 and the second sealing member 30 in the sandwich type device 2 are very thin substrates each made of a brittle material such as glass or crystal. Therefore in the sandwich type device 2, the strength of a center part (i.e. a region of the piezoelectric resonator plate 10 where the external frame part 14 does not exist) is especially low. In such a case, when the thin plate-like thermistor 5 is located inside the region of the center part of the sandwich type device 2, a pressing force applied to the sandwich type device 2 for mounting the thin plate-like thermistor 5 thereon may generate cracks of the first sealing member 20.

In contrast to the above, when the thin plate-like thermistor 5 is bonded to an outer peripheral part (i.e. a region of the piezoelectric resonator plate 10 where the external frame part 14 exists) of the sandwich type device 2, in other words, when the end parts of the thin plate-like thermistor 5 are located so as to be superimposed on the external frame part 14, it is possible to prevent cracks of the first sealing member 20 and thus to ensure the strength of the device 1. In particular, by superimposing the thin plate-like thermistor 5 on the sealing parts (i.e. the sealing patterns such as the resonator-plate-side first bonding pattern 113) of the sandwich type device 2, it is possible to provide the device 1 whose strength is more stable. Note that FIGS. 1 and 2 show an example in which both end parts of the thin plate-like thermistor 5 are superimposed on the external frame part 14 on the two sides, facing each other, of the sandwich type device 2 in the short-side direction. However, both end parts of the thin plate-like thermistor 5 may be superimposed on the external frame part 14 on the two sides, facing each other, of the sandwich type device 2 in the long-side direction. Furthermore, the thin plate-like thermistor 5 may be located so as not only to be superimposed on the two sides, facing each other, of the sandwich type device 2, but also to be superimposed on three or four sides thereof.

In the thin plate-like thermistor 5, the surface on which the split electrodes 53 are provided is a bottom surface (i.e. a surface to be bonded to the sandwich type device 2). Thus, the thin plate-like thermistor 5 is mounted on the sandwich type device 2 by electrically connecting the split electrodes 53 to the electrode patterns 211 of the first sealing member 20. In this time, a conductive resin adhesive 61 is preferably used between the split electrodes 53 and the electrode patterns 211 (see FIG. 2) so as to obtain electrical connection. However, the present invention is not limited thereto. The split electrodes 53 and the electrode patterns 211 may be bonded by Au (gold) bump. Furthermore, a gap between the thin plate-like thermistor 5 and the sandwich type device 2 (i.e. a gap where no conductive resin adhesive 61 exists) is preferably filled with a non-conductive resin adhesive 62 (see FIG. 2). Also, apart from using the non-conductive resin adhesive 62 to fill the gap below the thin plate-like thermistor 5, the non-conductive resin adhesive 62 may also be used to serve as a sealing resin that seals the whole thin plate-like thermistor 5. As the conductive resin adhesive 61, a silicone resin is preferably used. As the non-conductive resin adhesive 62, an epoxy resin is preferably used.

Like this, when the thin plate-like thermistor 5 is surface-bonded to the sandwich type device 2 via the conductive resin adhesive 61 and the non-conductive resin adhesive 62, it is possible to improve the thermal conductivity between the thin plate-like thermistor 5 and the sandwich type device 2. In this way, it is possible to keep the temperature of the thin plate-like thermistor 5 at a temperature close to that of the vibrating part 13 of the sandwich type device 2. Also, the surface bonding of the sandwich type device 2 and the thin plate-like thermistor 5 has an advantage that the strength of the device 1 is improved.

When using the conductive resin adhesive 61 and the non-conductive resin adhesive 62 to bond the thin plate-like thermistor 5, it is preferable that the thermal conductivity of the conductive resin adhesive 61 is higher than the thermal conductivity of the non-conductive resin adhesive 62. In this way, it is possible to further improve the thermal conductivity between the thin plate-like thermistor 5 and the sandwich type device 2. Also, it is preferable that the hardness of the non-conductive resin adhesive 62 is higher than the hardness of the conductive resin adhesive 61. In this way, it is possible to release stress between the thin plate-like thermistor 5 and the sandwich type device 2 while improving the strength of the package of the device 1.

The foregoing embodiment is to be considered in all respects as illustrative and not limiting. The technical scope of the present invention is indicated by the appended claims rather than by the foregoing description, and all modifications and changes that come within the meaning and range of equivalency of the claims are intended to be embraced therein.

For example, the device 1 as described above has a configuration in which the thin plate-like thermistor 5 is mounted on the sandwich type device 2, and it is exemplarily shown as a device used as a piezoelectric resonator. However, it may be a devise used as a piezoelectric oscillator further including an IC chip mounted on the thin plate-like thermistor 5.

The foregoing embodiment is to be considered in all respects as illustrative and not limiting. The technical scope of the present invention is indicated by the appended claims rather than by the foregoing description, and all modifications and changes that come within the meaning and range of equivalency of the claims are intended to be embraced therein.

For example, the device 1 as described above has a configuration in which the thin plate-like thermistor 5 is mounted on the sandwich type device 2, and it is exemplarily shown as a device used as a piezoelectric resonator. However, it may be a devise used as a piezoelectric oscillator further including an IC chip mounted on the thin plate-like thermistor 5.

### Embodiment 2

Hereinafter, another embodiment of the present invention is described in detail with reference to the drawings. In this embodiment, the thermistor-mounting piezoelectric resonator device of the present invention is applied to a crystal resonator device with a thermistor. In this embodiment (Embodiment 2), the same reference numerals as those in Embodiment 1 are used to refer to the components that have the same functions/configurations as those of the thermistor-mounting piezoelectric resonator device 1 according to Embodiment 1, even when their shapes in the Figures are different.

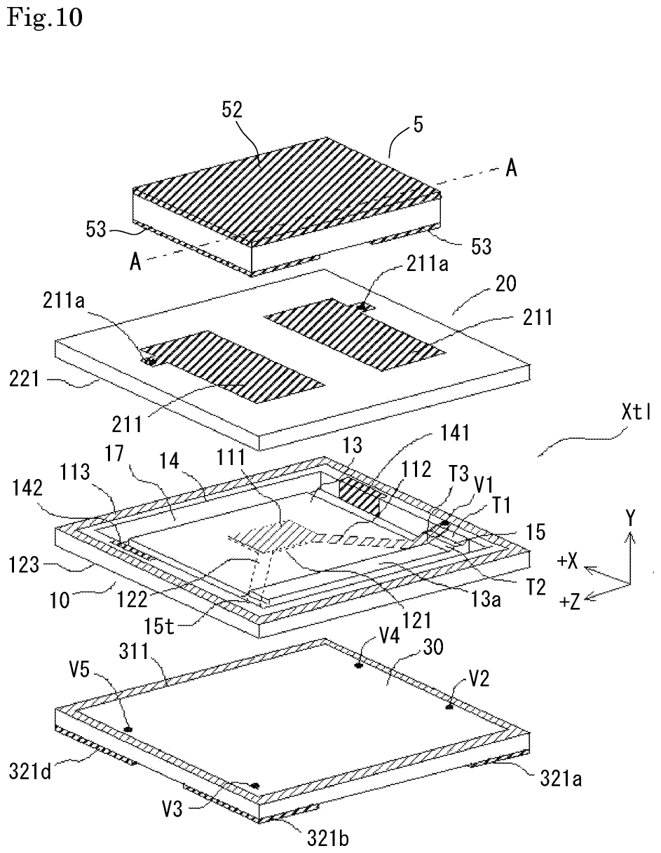

The crystal resonator device with a thermistor according to this embodiment is constituted of a crystal resonator device Xtl and a thermistor (corresponding to the thin plate-like thermistor 5). As shown in FIG. 10, the crystal resonator device Xtl is constituted of: a crystal resonator plate (corresponding to the piezoelectric resonator plate 10); the first sealing member 20; and the second sealing member 30. The first sealing member 20, the piezoelectric resonator plate 10 and the second sealing member 30 are superimposed and laminated in this order from top to bottom. Also, the thermistor 5 is conductively bonded to a top surface of the crystal resonator device Xtl.

The piezoelectric resonator plate 10 is made of an AT-cut crystal resonator plate, and its overall shape is a rectangular plate. The piezoelectric resonator plate 10 is constituted of: the vibrating part 13; support parts 15 and 15t that are respectively connected to two corner parts of the vibrating part 13; and the external frame part 14 that are provided on an outer periphery of the vibrating part and that are connected to the support parts 15 and 15t. Between the vibrating part 13 and the external frame part 14, a surrounding penetrating part 17 is formed except for the parts on which the support parts 15 and 15t are provided.

The vibrating part 13 has a rectangular shape constituted of a pair of long sides facing each other and a pair of short sides facing each other, which make four corner parts. Alternatively, the vibrating part may have a square shape in plan view. Almost on the center of the vibrating part 13, a rectangular-shaped first excitation electrode 111 and a rectangular-shaped second excitation electrode 121 are formed respectively on a first main surface and a second main surface (i.e. on the front and rear main surfaces). A strip-shaped first lead-out electrode 112 and a strip-shaped second lead-out electrode 122 are connected to respective corner parts of the first excitation electrode 111 and the second excitation electrode 121 so that the first lead-out electrode 112 and the second lead-out electrode 122 are drawn toward both end parts of an end side (i.e. corner parts of the vibrating part). The first lead-out electrode 112 and the second lead-out electrode 122 are drawn to the external frame part 14, respectively via the support part 15 and the support part 15t, and finally drawn to respective external electrode terminals 321a and 321b formed on the second sealing member 30, which are described later.

Specifically, the first lead-out electrode 112 passes on the front surface of the support part 15, and is drawn to the second main surface via a metal via hole (through metal) V1 formed in the external frame part 14, and furthermore is connected to a metal via hole V2 formed in the second sealing member 30 (described later). The metal via hole V2 is electrically connected to the external electrode terminal 321a formed on the second main surface of the second sealing member 30. On the other hand, the second lead-out electrode 122 passes on the rear surface of the support part 15t, and is drawn to the second main surface of the piezoelectric resonator plate 10 so as to be electrically connected to a metal via hole V3 formed in the second sealing member 30 facing the piezoelectric resonator plate 10. The metal via hole V3 is electrically connected to the external electrode terminal 321b formed on the second main surface of the second sealing member 30.

The first excitation electrode 111 and the second excitation electrode 121, and the first lead-out electrode 112 and the second lead-out electrode 122 are each made of a plurality of layers of metal films, having, for example, a multi-layer structure in which a Ti film is formed to make contact with the piezoelectric resonator plate 10, and an Au film is formed thereon. As a specific example of the thickness of each metal film, the Ti film is 5 nm, and the Au film is 200 nm. However, the thickness may be changed depending on desired characteristics.

On an end side of the vibrating part 13, a thick part 13a is formed. The thick part 13a is on the end side in the X axis direction so as to extend in the Z′ axis direction and to cover the whole end side. The thick part 13a has a thickness larger than the thickness of the vibrating part 13.

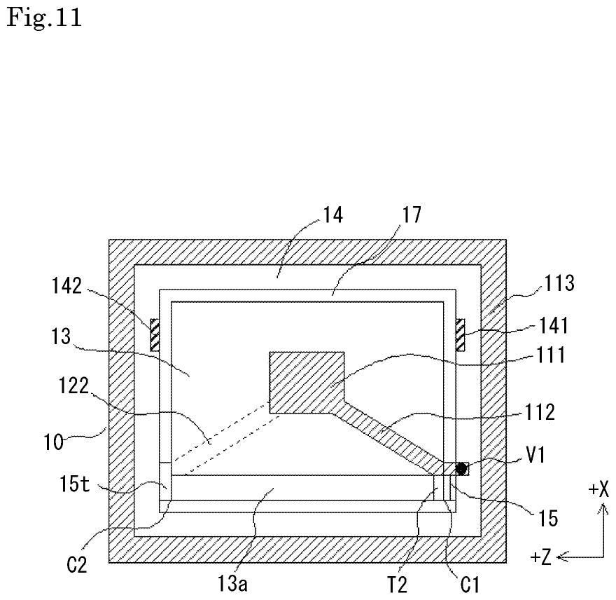

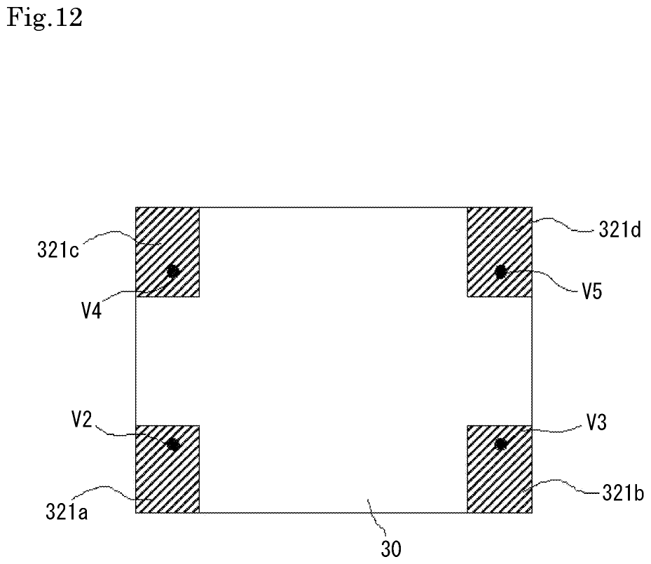

As shown in FIG. 11, the support part 15 is provided on one corner part C1 of the vibrating part 13, while the support part 15t is provided on the other corner part C2. The support parts 15 and 15t are respectively connected to the external frame part 14. In this embodiment, the vibrating part, the support part and the frame body part are integrally formed from a crystal plate using a photolithography technology and a wet etching technology. In place of the wet etching, a dry etching technology may also be used.

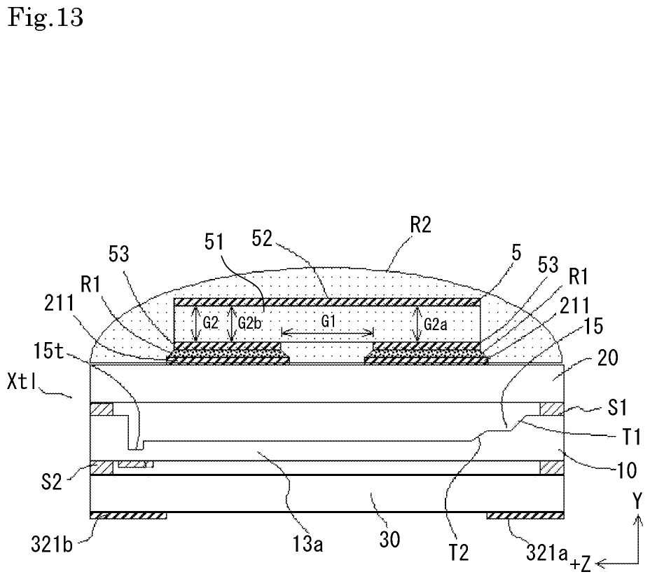

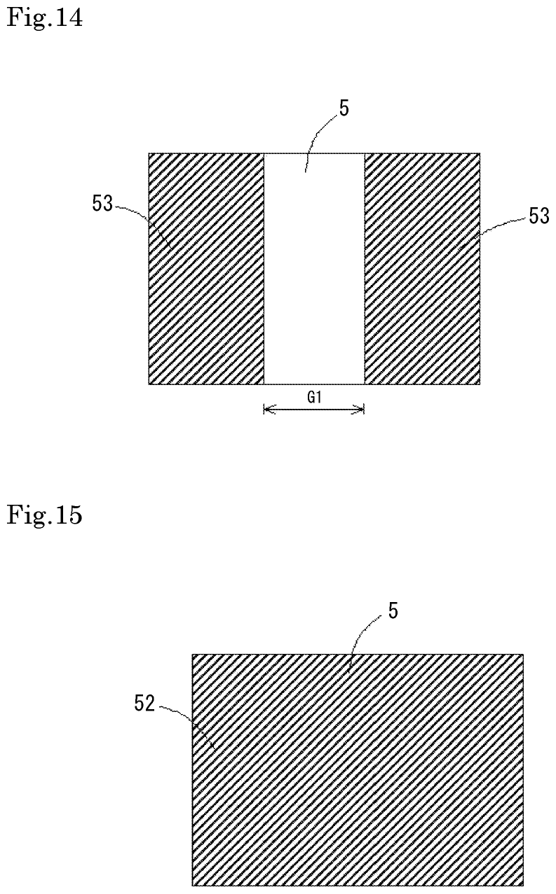

As shown in FIGS. 10 and 13, the support part 15 is formed thicker than the vibrating part 13 and the thick part 13a. Furthermore, on the top surface extending from the thick part 13a to the support part 15, a slope-shaped taper part T2 is formed, while on the top surface extending from the vibrating part 13 to the support part 15, a slope-shaped taper part T3 is formed. Also, the support part 15 is connected to the external frame part 14, and on the top surface extending from the support part 15 to the external frame part 14, a taper part T1 is formed. In this configuration, the thickness of each of the above parts is set to satisfy the following condition: the vibrating part<the thick part<the support part<the frame body part. However, the thickness of the thick part 13a and the thickness of the support part 15 may be the same. By forming the respective taper parts, it is possible to make boundary areas have obtuse angles. In the case where the steps of the boundary areas are small and thus disconnection is not likely to occur, the above taper parts are not necessarily required to be formed for practical use.

Here, a specific example of the respective sizes of the piezoelectric resonator plate 10 is shown. A rectangular-shaped At-cut crystal plate is used for the piezoelectric resonator plate 10, and its external size is 1.2 mm in width and 1.0 mm in length. The external size of the vibrating part 13 is 0.7 mm in width and 0.7 mm in length. Each width of the external frame part 14 is 0.2 mm in the width direction and 0.1 mm in the length direction. The size of the support part 15 is 0.05 mm in width and 0.15 mm in length. As to each thickness of the components, the thickness of the external frame part 14 is 0.04 mm, the thickness of the support part 15 is 0.03 mm, the thickness of the thick part 13a is 0.017 mm (17 μm), and the thickness of the vibrating part 13 is 0.005 mm (5 μm). In order to ensure the mechanical strength, it is preferable that the thickness of the thick part 13a is at least ten and several μm larger than the thickness of the vibrating part 13.

In this embodiment, the piezoelectric resonator plate 10 is thinned from only one main surface. For example, the thinning processing is performed from only one main surface side by etching technology to obtain a desired frequency (thickness). In this case, no etching is performed to the other main surface, thus it is possible to prevent degradation of the vibration characteristics due to a roughened surface by the etching. However, the thinning processing may be performed from both the main surfaces.

On the respective front and rear outer peripheral edges of the external frame part 14, annular-shaped sealing films (corresponding to the resonator-plate-side first bonding pattern 113 and the resonator-plate-side second bonding pattern 123) are formed. Similarly to the electrode films as described above, these sealing films each have a multi-layer structure made of a Ti film formed so as to make contact with the piezoelectric resonator plate 10 and an Au film formed thereon.

Also, connection electrodes 141 and 142 are formed respectively on the inner peripheral side of the external frame part 14 so as to be distantly positioned from the support part 15. The connection electrodes 141 and 142 are each made of a strip-shaped metal film that is formed on the top surface of the external frame part 14 so as to pass along the inner side surface thereof and to reach the bottom surface of the external frame part 14. The connection electrodes 141 and 142 are electrically connected to the respective electrode pads (corresponding to the split electrodes 53) of the thermistor 5 (described later), and also are electrically connected to the respective external electrode terminals 321c and 321d of the second sealing member 30.

The first sealing member 20 is made of a rectangular plate-like AT-cut crystal resonator plate, and has the external shape and the external size substantially the same as those of the piezoelectric resonator plate 10. On the second main surface (a surface facing the piezoelectric resonator plate 10) of the first sealing member 20, an annular-shaped sealing film (corresponding to the sealing-member-side first bonding pattern 221) is formed so as to be superimposed on the resonator-plate-side first bonding pattern 113.

On the first main surface of the first sealing member 20, a pair of rectangular-shaped electrode pads (corresponding to the electrode patterns 211) having long sides and short sides is formed so as to be arranged parallel to each other. In each electrode pad 211, an electrode is drawn from a connection electrode 211a to the second main surface via a metal via hole.

The second sealing member 30 is made of a rectangular plate-like AT-cut crystal resonator plate, and has the external shape and the external size substantially the same as those of the piezoelectric resonator plate 10. On a surface of the second sealing member 30, which faces the piezoelectric resonator plate 10, an annular-shaped sealing film (corresponding to the sealing-member-side second bonding pattern 311) is formed so as to be superimposed on the resonator-plate-side second bonding pattern 123.

On a surface of the second sealing member 30, which does not face the piezoelectric resonator plate 10, external electrode terminals 321a to 321d are formed. The external electrode terminals 321a to 321d each have a rectangular shape, and are formed on respective corner parts of the second sealing member 30. The external electrode terminals 321a and 321b are respectively electrically connected to the first excitation electrode 111 and the second excitation electrode 121. The external electrode terminals 321c and 321d are respectively connected to the terminals 53 and 53 of the thermistor 5. Each metal film constituting the external electrode terminals 321 has a laminated structure made of a Ti film, a NiTi film and an Au film.

In the second sealing member 30, in the vicinity of the region corresponding to the support part 15, the metal via hole V2 penetrating the front and rear surfaces is formed so as to be electrically connected to the above-described metal via hole V1. Also in the vicinity of the region corresponding to the support part 15t, the metal via hole V3 penetrating the front and rear surfaces is formed. With this configuration, the first lead-out electrode 112 formed on the piezoelectric resonator plate 10 is connected to the external electrode terminal 321a via the metal via hole V2, while the second lead-out electrode 122 is connected to the external electrode terminal 321b via the metal via hole V3. Furthermore, metal via holes V4 and V5 respectively corresponding to the connection electrodes 141 and 142 are formed so as to be respectively electrically connected to the external electrode terminals 321c and 321d. In this configuration, the external electrode terminals 321a and 321b for the crystal resonator device are arranged in the long side direction so as to face each other, and the external electrode terminals 321c and 321d for the thermistor are arranged in the long side direction so as to face each other. Alternatively, the two external electrode terminals 321a and 321b for the crystal resonator device Xtl may be diagonally disposed and furthermore the two external electrode terminals 321c and 321d for the thermistor may be diagonally disposed, by changing the design of the electrode wiring.

The thermistor 5 is electrically and mechanically connected to the electrode pads 211 and 211 of the first sealing member 20. The thermistor 5 has a rectangular plate-like NTC thermistor. A rectangular plate-like thermistor element (corresponding to the thermistor flat plate 51) has a thickness of G2. The common electrode 52 is formed so as to cover the whole first main surface of the thermistor element 51 while the rectangular-shaped electrode pads 53 and 53 are formed on the second main surface so as to have a constant gap G1 therebetween in the long side direction.

In the thermistor 5, the pair of electrode pads 53 and 53 formed on the thermistor element 51 each serves as a terminal as a resistor. The conductive path leads from one electrode pad 53 to the other electrode pad 53 via the common electrode 52. With this configuration, it is possible to considerably increase the cross sectional area of the conductive path, and also to provide the conductive path in which the surface of the common electrode 52 faces the surfaces of the electrode pads 53 and 53. Thus, it is possible to reduce the resistance value with a small area, which leads to characteristics easily stabilized and an improved withstand voltage.

When the electrode pads 53 and 53 are adjacent to each other, a path between the electrode pads 53 and 53 is sometimes dominant as the conductive path depending on the voltage applied, with the result that the desired resistance value cannot be obtained. Therefore, in this embodiment, a distance G2a, a distance G2b and the distance G1 are set to satisfy the following inequality: G2a+G2b<G1, where G2a represents the distance between one electrode pad 53 and the common electrode 52, G2b represents the distance between the other electrode pad 53 and the common electrode 52, and G1 represents the distance between the electrode pads 53 and 53. With this setting, it is possible to obtain the desired resistance value, which leads to stabilization of accuracy of the thermistor.

The larger the contact area of the thermistor 5 with the crystal resonator device Xtl becomes, the more exactly the temperature of the crystal resonator device Xtl can be detected. Therefore, the area occupied by the electrode pads 53 and 53 formed on the thermistor 5 are preferably large with respect to the area of the thermistor 5. However, if the area of the electrode pads 53 and 53 is too large, a short circuit between the adjacent electrode pads or a short circuit caused by the conductive bonding material is likely to occur. On the other hand, when the contact area becomes small, the accuracy in detection of the temperature of the crystal resonator device Xtl is degraded. Thus, when the total area of the electrode pads 53 and 53 occupies 40 to 85% of the area of the thermistor 5, it is possible to stably detect the temperature, although it also depends on the desired resistance value. When the total area occupies not more than 40%, the electrode pads of the thermistor 5 are too small and thus it is not possible to correctly detect the temperature information on the crystal resonator device Xtl. Furthermore, the resistance value becomes too high, and thus it may degrade the temperature detection performance of the thermistor 5. When the total area occupies not less than 85%, the risk of short circuit including the case caused by the conductive bonding material increases, and once the short circuit occurs, the thermistor 5 does not function as a thermistor any more.

Here, a specific example of the respective sizes is shown. As the external size of the thermistor 5 (i.e. the external size of the thermistor element 51), the long side is 0.8 mm, the short side is 0.6 mm, the thickness is 0.05 mm, and the area is 0.48 mm². As the external size of each electrode pad 53 formed on the thermistor element 51, the long side (i.e. in the short side direction of the thermistor element 51) is 0.52 mm, the short side (i.e. in the long side direction of the thermistor element 51) is 0.3 mm, and the area is 0.156 mm². With this configuration, the total area of the electrode pads 53 and 53 is set to about 65% of the area of the thermistor 5. Also, the distances G2a and G2b between the common electrode 52 and the respective electrode pads 53 and 53 are each 0.05 mm. The distance G1 between the respective electrode pads is set to 0.12 mm. Thus, the above-described inequality G2a+G2b<G1 is satisfied.

Another specific example is shown below. As the external size of the thermistor 5 (i.e. the external size of the thermistor), the long side is 0.7 mm, the short side is 0.6 mm, the thickness is 0.04 mm, and the area is 0.42 mm². As the external size of each electrode pad 53 formed on the thermistor element 51, the long side (i.e. in the short side direction of the thermistor element 51) is 0.58 mm, the short side (i.e. in the long side direction of the thermistor element 51) is 0.3 mm, and the area is 0.174 mm². With this configuration, the total area of the electrode pads 53 and 53 is set to about 83% of the area of the thermistor 5. Also, the distances G2a and G2b between the common electrode 52 and the respective electrode pads 53 and 53 are each 0.04 mm. The distance G1 between the respective electrode pads is set to 0.09 mm. Thus, the above-described inequality G2a+G2b<G1 is satisfied. The above sizes may be appropriately designed according to the sizes and characteristics of the crystal resonator device Xtl, or to the required specifications of the crystal resonator device with a thermistor.

As the plate-like thermistor, a Mn—Fe—Ni—Ti material is made into slurry with a binder. Then, a green sheet of the thermistor wafer is prepared using a thick film formation technology such as a screen printing technology or a doctor blade technology. This is subjected to firing technology so as to sinter and form the plate-like thermistor wafer.

On the plate-like thermistor wafer, an electrode film (metal film) is formed by sputtering, and then patterning is performed by a photolithography technology. As specific metal materials, a Ti film, a NiTi film and an Au film may be used so as to make a laminated structure similarly to the metal films constituting the terminal electrodes. Also, other types of metal films may be used. In the case where the above laminated structure constituted of the Ti film, the NiTi film and the Au film is adopted, it is possible to perform stable conductive bonding with low occurrence of solder leaching when the thermistor is finally bonded to the mounting board by solder. Also, the metal film structure of the electrode pads 53 and 53 may be different from the metal film structure of the common electrode 52. For example, the metal film structure of the electrode pads 53 and 53 may be the laminated structure constituted of the Ti film, the NiTi film and the Au film as described above, while the metal film structure of the common electrode 52 may be a laminated structure constituted of the Ti film and the Au film.

In this way, by forming the metal films to be the electrode pads 53 and 53 as well as the common electrode 52 on the single layer and plate-like thermistor element 51 by a thin film forming method such as sputtering, an extremely thin plate-like thermistor can be obtained. In the plate-like thermistor, the surface roughness can be decreased by lapping its surface in the state of the thermistor wafer. In this configuration, it is possible to stably form the electrode film (metal film) and also to improve manufacturing accuracy. Thus, the performance of the thermistor 5 can be highly improved.

As shown in FIG. 13, the crystal resonator device Xtl has a structure in which the first sealing member 20, the piezoelectric resonator plate 10 and the second sealing member 30 are superimposed and laminated in this order from top to bottom. As described above, each of the above components is made of a crystal plate, and its surface is a smooth surface by mirror polishing. As a specific example, the advantage surface roughness Ra preferably meets the following condition: Ra=0.3 to 0.1 nm. By forming the sealing film on the above smooth surface, the metal film on the surface (i.e. the Au film as the uppermost layer) has also a very smooth surface.

The bonding of the first sealing member 20 and the piezoelectric resonator plate 10 as well as the bonding of the piezoelectric resonator plate 10 and the second sealing member 30 are performed as a pressure bonding by a diffusion bonding method after the surface treatment is performed to Au on the metal films. In this way, the vibrating part 13 of the piezoelectric resonator plate 10 is hermetically sealed in a state in which it is surrounded by the first and second sealing members 20 and 30 and the external frame part 14, which are bonded by the sealing parts S1 and S2 made by bonding of the sealing films. The hermetically sealed interior is in a vacuum state or in an inert gas atmosphere.

The thermistor 5 is mounted on the top surface of the above-configured crystal resonator device Xtl, i.e. on the first main surface of the first sealing member 20. More specifically, the electrode pads 211 and 211 formed on the top surface of the crystal resonator device Xtl are respectively surface-bonded to the electrode pads 53 and 53 formed on the thermistor 5 made of the plate-like thermistor via conductive bonding materials (for example, the conductive resin adhesives 61) R1 and R1. The each area of the electrode pads 211 and 211 is larger than the corresponding area of the electrode pads 53 and 53. In this way, since the crystal resonator device Xtl and the thermistor 5 can be subjected to conductive bonding by the conductive bonding materials R1 and RI including fillets, it is possible to improve the bonding strength therebetween. The conductive bonding material R1 is made by adding conductive fillers such as silver powder and silver pieces to pasty silicone resin bonding material. Thus, the conductive bonding material R1 has an excellent thermal conductivity. By the above feature in addition to the surface bonding of the electrode pads, excellent thermal conduction is obtained, which leads to high-precision measurement as the detection of the temperature of the crystal resonator device Xtl by the thermistor 5 with reduced time lag. In the case where the conductive bonding material R1 is the conductive resin adhesive 61, a resin other than the silicone resin (for example, an urethane resin and an epoxy resin) may be used. Also, the conductive bonding material R1 is not limited to the conductive resin adhesive 61, but may be solder.

In this embodiment, the thermistor 5 made of the plate-like thermistor is covered by a resin material R2, as shown in FIG. 13. The resin material R2 covers the top surface of the crystal resonator device Xtl, and accordingly covers the thermistor 5, the electrode pads 211 and 211 provided on the crystal resonator device Xtl, and the conductive bonding materials R1. The resin material R2 used here is made by adding silica (SiO₂) fillers to an epoxy resin, and its thermal conductivity is lower than the thermal conductivity of the conductive bonding material R1. As the resin material R2, a resin material other than the epoxy resin (for example, an urethane resin and a silicone resin) may be used. With this configuration, it is possible to obtain an effect that the heat detected by the thermistor 5 is prevented from escaping outside.

With the above-described configuration, it is possible, with reduced time lag, to detect changes of the temperature of the crystal resonator device Xtl by the thermistor 5 via the electrode pads 211 and 53, and the conductive bonding materials R1. Also, since the thermistor 5 is covered by the resin material whose thermal conductivity is lower than the thermal conductivity of the conductive bonding material, the heat absorbed by the thermistor 5 does not escape outside. Therefore, the temperature at which the crystal resonator device Xtl operates can be precisely detected, which results in the temperature detection with high accuracy. On the top surface of the crystal resonator device Xtl, IC components including an oscillation circuit and a temperature compensation circuit may be mounted in addition to the thermistor 5 so that the IC components are also conductively bonded to the crystal resonator device Xtl and the thermistor 5. By this configuration, it is possible to obtain the crystal resonator device having a structure of a temperature-compensated crystal oscillator.

On the vibrating part 13 in this embodiment, the thick part 13a is formed along almost whole of one end side on which the support parts 15 and 15t are provided, while the other end sides each have a thickness of a thin resonator plate that addresses high frequency. Therefore, the vibration excited by the vibrating part 13 is not likely to be affected by the boundary condition due to the thick part 13a. Thus, it is possible to obtain the piezoelectric resonator plate 10 that is not likely to generate spurious vibration and that can maintain a good CI value (series resonance resistance). Furthermore, the mechanical strength of the vibrating part 13 can be improved by the thick part 13a.

Also, as described above, the support part 15 has a thickness larger than or equal to the thickness of the thick part 13a. Furthermore, the taper parts are respectively formed between the external frame part 14 and the support part 15, and between the thick part 13a and the vibrating part 13. Thus, by formation of the taper parts, it is possible to make the boundary areas have obtuse angles, as described above. In this way, the first and second lead-out electrodes 112 and 122 that are drawn from the first and second excitation electrodes 111 and 121 to one end side of the piezoelectric resonator plate 10 are formed respectively on the taper parts and thus do not pass through the corner part areas (step parts) with acute angles. Thus, it is possible to prevent conduction failure and disconnection of the electrodes, which results in obtainment of the piezoelectric resonator plate 10 having excellent electrical characteristics.

In this embodiment, the external frame part 14 and the vibrating part 13 are connected by the plurality of support parts 15 and 15t, and the thickness of the support part 15t is smaller than the thickness of the support part 15. Therefore, it is possible to stabilize the mechanical strength by supporting by the plurality of support parts, and at the same time to reduce prevention of vibration of the vibrating part by thus providing the support part with a smaller thickness (i.e. a thinner support part). Thus, it is possible to prevent degradation of the electrical characteristics of the crystal resonator device Xtl and thus to ensure electrical performance on practical side. Also, the present invention is not limited to this embodiment. The vibrating part 13 may be connected by only one support part 15.

In the piezoelectric resonator plate 10, a thin part may be provided in place of the penetrating part 17. In this case, the vibrating part is connected to the frame body part via the support part and the thin part.

In this embodiment, the multi-layer structure constituted of Ti and Au is exemplarily described as the metal film of the first and second excitation electrodes 111 and 121 as well as the metal film for sealing (i.e. sealing film). However, the metal film structure is not limited thereto. For example, the metal film may have a multi-layer structure of Ti, NiTi and Au.

Also, the piezoelectric resonator plate 10 is bonded to the first and second sealing members 20 and 30 by the diffusion bonding. However, the bonding may be performed by brazing, using, for example, an AuSn alloy as a brazing material. Also, another brazing material such as a Sn brazing alloy may be used.

In this brazing, the structure of the metal film may also be different. For example, the following structures may be adopted: a structure in which a Ag/a Cu film is formed on a Cr base layer; and a structure in which an alloy film is formed by a Cr base layer and Au.

In the above description, a crystal plate is used as the material of the first and second sealing members 20 and 30. However, glass or ceramic may also be used in place of the crystal plate. As to the shape thereof, the plate-like structure is exemplarily shown. However, the first and second sealing members 20 and 30 may each have a recess part at a position facing the piezoelectric resonator plate 10. In the case where the recess parts are provided, it is possible to decrease the opportunity to bring the vibrating part 13 into contact with the first and second sealing members 20 and 30. Thus, it is possible to stabilize the characteristics of the crystal resonator device Xtl.

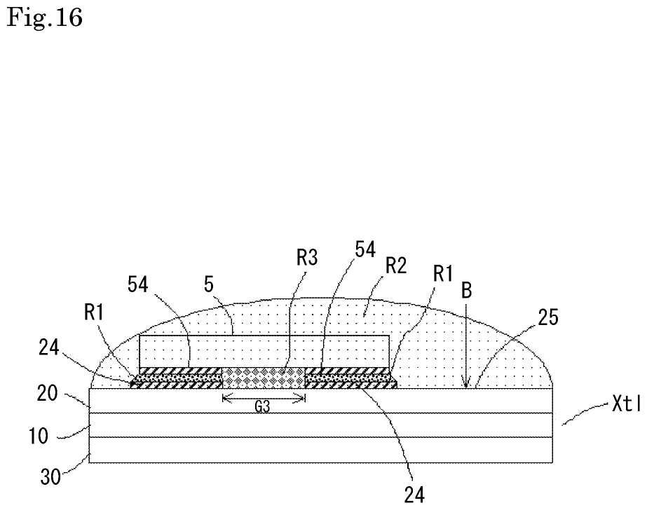

Here, a variation of Embodiment 2 is described with reference to FIG. 16. In FIG. 16, the detailed configuration of the crystal resonator device Xtl is omitted. In this variation also, the thermistor 5 is mounted on the top surface of the crystal resonator device Xtl. However, the configuration and arrangement of the thermistor 5 are different.

On the top surface of the first sealing member 20, electrode pads 24 and 24 are formed. Unlike the example shown in FIG. 13, these electrode pads 24 and 24 are formed so as to be displaced to the left side of the figure. In the result of this arrangement, a region where the electrode pads 24 and 24 are not formed can be ensured on the top surface of the first sealing member 20. This region can be used as an adjustment region 25. When the first sealing member 20 is made of a transparency material, an energy beam B such as a laser beam can pass through the adjustment region 25. Accordingly, by irradiating the metal films formed on the piezoelectric resonator plate 10 with the energy beam, it is possible to remove part of the metal films, which allows adjustment of the frequency of the crystal resonator device Xtl.

Also, an adjustment metal film may be formed on an inner side of the first sealing member 20 in advance. By irradiating the adjustment metal film with the energy beam, the adjustment metal film is vaporized and adhered to the metal films formed on the piezoelectric resonator plate 10. Thus, the frequency of the crystal resonator device Xtl can be adjusted.

In this thermistor 5, electrode pads 54 and 54 are formed on a second main surface of the thermistor element, and thus an electrode gap G3 is formed. However, no electrode film is formed on a first main surface of the thermistor element. Therefore, a conductive path is formed between the electrode pads 54 and 54, which leads to the function as the thermistor.

By bonding the electrode pads 54 and 54 respectively to the electrode pads 24 and 24 via the conductive bonding materials R1 made of solder, both electrode pads 54 and 24 are conductively surface-bonded, which leads to bonding with excellent thermal conductivity. In the example shown in FIG. 16, a gap between the conductive bonding materials R1 and R1 is filled with an insulating resin material R3 with excellent thermal conductivity. In this configuration, the whole second main surface of the thermistor 5 is surface-bonded to the crystal resonator device Xtl.

The whole top surface (i.e. the first main surface) of the first sealing member 20 is covered by the resin material R2. Thus, the whole thermistor 5 is also covered by the resin material R2. Alternatively, the resin material R2 may be formed to cover only the region where the thermistor 5 is mounted. In such a case, since the adjustment region 25 is not covered by the resin material R2, the configuration has an advantageous effect that the frequency adjustment can be performed with the energy beam B after bonding the thermistor.

In this variation, since the almost whole second main surface of the thermistor 5 is bonded to the crystal resonator device Xtl by the conductive bonding material (solder) R1 and the insulating resin material R3, the thermistor 5 can reliably and accurately capture changes of the temperature of the crystal resonator device Xtl. Also, since the thermistor 5 is covered by the resin material R2, it is possible to reduce dissipation of the heat. Thus, it is possible to obtain the crystal resonator device with a thermistor, which can accurately detect the temperature.

Furthermore, by making the adjustment region 25, the frequency of the crystal resonator device Xtl can be adjusted after hermetically sealing or after mounting the thermistor 5, which improves the electrical characteristics.

Note that the configuration of the coating resin (resin material R2) in Embodiment 2 can be naturally combined with the thermistor-mounting piezoelectric resonator device 1 in Embodiment 1.

This application claims priority based on Patent Application No. 2021-178744 filed in Japan on Nov. 1, 2021 and also on Patent Application No. 2021-178745 filed in Japan on Nov. 1, 2021. The entire contents thereof are hereby incorporated in this application by reference.

### Description of the Reference Numerals

1 Thermistor-mounting piezoelectric resonator device
2 Sandwich type device (piezoelectric resonator device having sandwich structure)
10 Piezoelectric resonator plate
11 First main surface (of piezoelectric resonator plate)
111 First excitation electrode
112 First lead-out wiring
113 Resonator-plate-side first bonding pattern
114-116 Connection bonding pattern
12 Second main surface (of piezoelectric resonator plate)
121 Second excitation electrode
122 Second lead-out wiring
123 Resonator-plate-side second bonding pattern
124, 125 Connection bonding pattern
13 Vibrating part
14 External frame part
15 Support part
16 Through hole
20 First sealing member
21 First main surface (of first sealing member)
211 Electrode pattern
212, 213 Wiring pattern
22 Second main surface (of first sealing member)
221 Sealing-member-side first bonding pattern
222-225 Connection bonding pattern
226 Wiring pattern
23 Through hole
30 Second sealing member
31 First main surface (of second sealing member)
311 Sealing-member-side second bonding pattern
312 Connection bonding pattern
32 Second main surface (of second sealing member)
321 External electrode terminal
33 Through hole
5 Thin plate-like thermistor
51 Thermistor flat plate
52 Common electrode
53 Split electrode
61 Conductive resin adhesive
62 Non-conductive resin adhesive
5 S1, S2 Sealing part
T1, T2, T3 Taper part
V1, V2, V3, V4, V5 Metal via hole
R1 Conductive bonding material
R2 Resin material
R3 Insulating resin material

1. A thermistor-mounting piezoelectric resonator device comprising:
a piezoelectric resonator device having a sandwich structure, the piezoelectric resonator device including: a piezoelectric resonator plate having a vibrating part on a first main surface of which a first excitation electrode is formed and on a second main surface of which a second excitation electrode is formed; a first sealing member laminated so as to cover the first main surface side of the piezoelectric resonator plate; and a second sealing member laminated so as to cover the second main surface side of the piezoelectric resonator plate, the piezoelectric resonator plate being bonded to the first sealing member and the second sealing member so as to form an internal space in which the vibrating part is hermetically sealed; and
a thin plate-like thermistor mounted on an outer surface of the first sealing member of the piezoelectric resonator device, wherein
the thin plate-like thermistor is located so as to be superimposed on at least a part of the vibrating part in plan view.

2. The thermistor-mounting piezoelectric resonator device according to claim 1, wherein
the thin plate-like thermistor is located so as to be superimposed on whole of the first excitation electrode and the second excitation electrode in plan view.

3. The thermistor-mounting piezoelectric resonator device according to claim 1, wherein
in the thin plate-like thermistor, a common electrode is formed on a first main surface of a thermistor flat plate as a single plate, and split electrodes are formed on a second main surface thereof, and
the common electrode is formed so as to cover almost whole of the first main surface of the thermistor flat plate.

4. The thermistor-mounting piezoelectric resonator device according to claim 1, wherein
in the thin plate-like thermistor, a common electrode is formed on a first main surface of a thermistor flat plate as a single plate, and split electrodes are formed on a second main surface thereof, and
the split electrodes occupy half or more of an area of the thermistor flat plate.

5. A thermistor-mounting piezoelectric resonator device comprising:
a piezoelectric resonator device having a sandwich structure, the piezoelectric resonator device including: a piezoelectric resonator plate having a vibrating part on a first main surface of which a first excitation electrode is formed, and on a second main surface of which a second excitation electrode is formed; a first sealing member laminated so as to cover the first main surface side of the piezoelectric resonator plate;
and a second sealing member laminated so as to cover the second main surface side of the piezoelectric resonator plate, the piezoelectric resonator plate being bonded to the first sealing member and the second sealing member so as to form an internal space in which the vibrating part is hermetically sealed; and
a thin plate-like thermistor mounted on an outer surface of the first sealing member of the piezoelectric resonator device, wherein
the piezoelectric resonator plate is provided with: the vibrating part; an external frame part surrounding an outer periphery of the vibrating part; and a support part supporting the vibrating part by connecting the vibrating part to the external frame part, and
the thin plate-like thermistor is located so as to be superimposed on the external frame part on two sides, facing each other, of the piezoelectric resonator device.

6. The thermistor-mounting piezoelectric resonator device according to claim 1, wherein
the thin plate-like thermistor and the piezoelectric resonator device are electrically connected to each other via a conductive resin adhesive, and furthermore a gap between the thin plate-like thermistor and the piezoelectric resonator device is filled with a non-conductive resin adhesive.

7. The thermistor-mounting piezoelectric resonator device according to claim 6, wherein
the conductive resin adhesive has a thermal conductivity higher than that of the non-conductive resin adhesive.

8. The thermistor-mounting piezoelectric resonator device according to claim 6, wherein
the non-conductive resin adhesive has a hardness higher than that of the conductive resin adhesive.

9. The thermistor-mounting piezoelectric resonator device according to claim 1, wherein
the first sealing member and the second sealing member are each made of a brittle material.

10. The thermistor-mounting piezoelectric resonator device according to claim 5, wherein
the thin plate-like thermistor and the piezoelectric resonator device are electrically connected to each other via a conductive resin adhesive, and furthermore a gap between the thin plate-like thermistor and the piezoelectric resonator device is filled with a non-conductive resin adhesive.

11. The thermistor-mounting piezoelectric resonator device according to claim 10, wherein
the conductive resin adhesive has a thermal conductivity higher than that of the non-conductive resin adhesive.

12. The thermistor-mounting piezoelectric resonator device according to claim 10, wherein
the non-conductive resin adhesive has a hardness higher than that of the conductive resin adhesive.

13. The thermistor-mounting piezoelectric resonator device according to claim 5, wherein
the first sealing member and the second sealing member are each made of a brittle material.
